(19) United States
(12) Patent Application Publication
(10) Pub. No.: US 2022/0139313 A1
(43) Pub. Date: May 5, 2022

(54) DISPLAY DEVICE AND ELECTRONIC APPARATUS

(71) Applicant: SONY SEMICONDUCTOR SOLUTIONS CORPORATION, KANAGAWA (JP)

(72) Inventor: TAKASHI TOYODA, KANAGAWA (JP)

(21) Appl. No.: 17/433,758

(22) PCT Filed: Feb. 18, 2020
(86) PCT No.: PCT/JP2020/006231

§ 371 Date: Aug. 25, 2021

(30) Foreign Application Priority Data
Mar. 8, 2019 (JP) 2019-042118

(51) Int. Cl. G09G 3/3225

(52) U.S. Cl. CPC G09G 3/3225; G09G 2300/0439

(57) ABSTRACT

A display device has a pixel array unit in which display elements that constitute pixels are arranged in a two-dimensional matrix in a row direction and a column direction, in which a display element includes a light emission part driven by current and a drive circuit for driving the light emission part, the drive circuit at least includes a constant current transistor, a drive transistor to which the light emission part and a source electrode are connected, the drive transistor being in source follower connection with the constant current transistor, and a capacitance unit that maintains gate voltage of the drive transistor, and the constant current transistor and the drive transistor are formed such that a ratio of a channel width to a channel length is the same.

### TECHNICAL FIELD

The present disclosure relates to a display device and an electronic apparatus.

### BACKGROUND ART

A display element including a current-driven light emission part and a display device including the display element are known. For example, a display element provided with a light emission part including an organic electroluminescence element is attracting attention as a display element capable of high-intensity light emission by low-voltage direct current drive.

A display device using organic electroluminescence is a self-luminous type, and further has sufficient responsiveness to a high-definition high-speed video signal. Display devices to be attached to an eyewear such as eyeglasses or goggles are also required to have a pixel size of about several micrometers to 10 micrometers, for example. A display element driven by an active matrix method includes a circuit for driving the light emission part, in addition to a light emission part constituted by an organic layer, or the like, including a light emission layer.

As a drive circuit for driving a current-driven light emission part, a circuit constituted by a transistor and a capacitance unit is well known (refer to FIG. 3B in Patent Document 1, for example). Examples of types of a drive circuit include a current control type that controls current flowing through a light emission part as in Patent Document 1, and a voltage control type that controls voltage applied to a light emission part.

### CITATION LIST

### Patent Document

Patent Document 1: Japanese Patent Application Laid-Open No. 2007-310311

### SUMMARY OF THE INVENTION

### Problems to be Solved by the Invention

Luminance of a current-driven light emission part is basically determined an amount of current flowing through the light emission part. Comparing a case where the light emission part is driven by using a current control type drive circuit and a case where the light emission part is driven by using a voltage control type drive circuit, the latter has a potential effect of variation in a voltage-to-current characteristic (V-I characteristic) in a light emission part. Therefore, in a case where the light emission part is driven by using a voltage control type drive circuit, it is preferable to reduce another factor of variation as much as possible. Specifically, it is preferable to supply voltage, with as little variation as possible among display elements, to a light emission part of the display elements that constitute pixels.

Therefore, an object of the present disclosure is to provide a display device capable of supplying voltage, with as little variation as possible among display elements, to a light emission part of the display elements that constitute pixels, and an electronic apparatus including the display device.

### Solutions to Problems

A display device according to the present disclosure for achieving the above-described object is a display device having

a pixel array unit in which display elements that constitute pixels are arranged in a two-dimensional matrix in a row direction and a column direction,

in which a display element includes a light emission part driven by current and a drive circuit for driving the light emission part,

the drive circuit at least includes

a constant current transistor,

a drive transistor to which the light emission part and a source electrode are connected, the drive transistor being in source follower connection with the constant current transistor, and

a capacitance unit that maintains gate voltage of the drive transistor, and

the constant current transistor and the drive transistor are formed such that a ratio of a channel width to a channel length is the same.

An electronic apparatus according to the present disclosure for achieving the above-described object is an electronic apparatus including a display device having

a pixel array unit in which display elements that constitute pixels are arranged in a two-dimensional matrix in a row direction and a column direction, in which

a display element includes a light emission part driven by current and a drive circuit for driving the light emission part,

the drive circuit at least includes

a constant current transistor,

a drive transistor to which the light emission part and a source electrode are connected, the drive transistor being in source follower connection with the constant current transistor, and

a capacitance unit that maintains gate voltage of the drive transistor, and

the constant current transistor and the drive transistor are formed such that a ratio of a channel width to a channel length is the same.

### BRIEF DESCRIPTION OF DRAWINGS

FIG. 1 is a conceptual diagram of a display device according to a first embodiment.

FIG. 2 is a schematic circuit diagram for describing a basic configuration of a pixel (display element) including a voltage drive type drive circuit.

FIG. 3 is a schematic circuit diagram for describing a specific configuration of a drive circuit used in a display device.

FIG. 4 is a schematic partial cross-sectional view of a part of a pixel array unit, the part including a display element.

FIG. 5 is a schematic plan view for describing disposition of transistors and the like on a drive circuit according to the first embodiment.

FIG. 6 is a schematic plan view for describing disposition of transistors and the like in a drive circuit of a reference example.

FIG. 7 is a schematic plan view for describing disposition of transistors and the like in a drive circuit of a first modification.

FIG. 8 is a schematic plan view for describing disposition of transistors and the like in a drive circuit of a second modification.

FIG. 9 is a schematic plan view for describing disposition of transistors and the like in a drive circuit of a third modification.

FIG. 10 is an external view of a lens interchangeable single-lens reflex type digital still camera of which front view is illustrated in FIG. 10A and rear view is illustrated in FIG. 10B.

FIG. 11 is an external view of a head-mounted display.

FIG. 12 is an external view of a see-through head-mounted display.

### MODES FOR CARRYING OUT THE INVENTION

Hereinafter, the present disclosure will be described on the basis of an embodiment with reference to the drawings. The present disclosure is not limited to the embodiment, and various numerical values and materials in the embodiment are examples. In the following description, the same reference signs will be used for the same elements or elements having the same function, and duplicate description will be omitted. Note that the description will be made in the following order.

1. Description of overall display device and electronic apparatus according to present disclosure

2. First Embodiment

3. Description of electronic apparatus, other

### Description of Overall Display Device and Electronic Apparatus According to Present Disclosure

As described above, a display device according to the present disclosure and a display device used for an electronic apparatus according to the present disclosure (hereinafter, may be simply referred to as “display device according to the present disclosure”) have a pixel array unit in which display elements that constitute pixels are arranged in a two-dimensional matrix in a row direction and a column direction, in which a display element includes a light emission part driven by current and a drive circuit for driving the light emission part, the drive circuit at least includes a constant current transistor, a drive transistor to which the light emission part and a source electrode are connected, the drive transistor being in source follower connection with the constant current transistor, and a capacitance unit that maintains gate voltage of the drive transistor, and the constant current transistor and the drive transistor are formed such that a ratio of a channel width to a channel length is the same.

In a display device according to the present disclosure, a constant current transistor and a drive transistor can be configured formed with the same transistor size.

In the display device according to the present disclosure including the above-described preferred configuration, the constant current transistor and the drive transistor can be configured formed adjacent to each other on a plane region on which the drive circuit is disposed. Qualitatively, a characteristic difference between transistors formed adjacent to each other is smaller than a characteristic difference between transistors formed apart from each other. With this arrangement, variation in voltage supplied to the light emission part can be further reduced.

In the display device according to the present disclosure including the above-described various preferred configurations, the constant current transistor and the drive transistor can be configured including a field-effect transistor of the same conductivity type. For example, the constant current transistor and the drive transistor may be configured including an re-channel field-effect transistor or a p-channel field-effect transistor.

As a current-driven light emission part used for the display device according to the present disclosure including the above-described various preferred configurations, an organic electroluminescence element, an LED element, a semiconductor laser element, or the like can be used. These elements can be configured by using a known material or method. From a viewpoint of configuring a flat display device, of all others, it is preferable that the light emission part be configured including an organic electroluminescence light emission part.

In the display device according to the present disclosure including the above-described various preferred configurations, the drive circuit can be configured further including a write transistor for writing signal voltage to a capacitance unit. In this case, the constant current transistor, the drive transistor, and the write transistor can be configured including a field-effect transistor of the same conductivity type.

Hereinafter, the display device and electronic apparatus according to the present disclosure may be simply referred to as the present disclosure. In the present disclosure, the drive circuit can be formed on a semiconductor substrate, an insulating substrate on which a semiconductor material layer is formed, or the like. In a case where the drive circuit is configured by a transistor formed on a semiconductor substrate, for example, it is only required to provide a well region on a semiconductor substrate including silicon and form a transistor in a well.

For example, various wirings used in the display device can be formed by combination of a known film formation method, such as a physical vapor deposition method (PVD method) exemplified by a vacuum deposition method and a sputtering method or various kinds of chemical vapor deposition method (CVD method), and a known patterning method such as an etching method or a lift-off method.

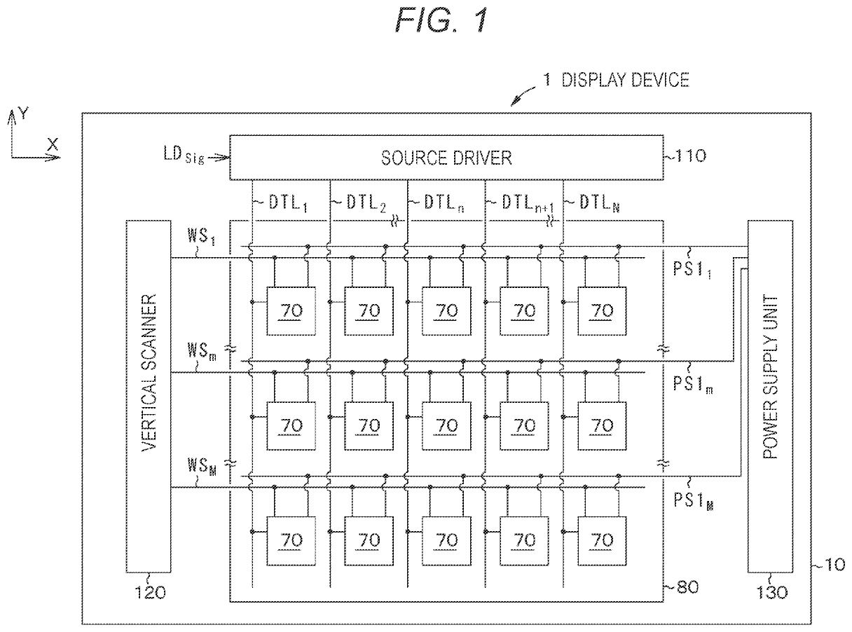

A source driver or the like that drives the display device may be integrated with a semiconductor substrate or the like on which the display element is disposed, or may be configured as a separate body as appropriate. These can be configured by using a known circuit element. For example, a vertical scanner and power supply unit illustrated in FIG. 1 can also be configured by using a known circuit element. In an application that requires miniaturization, such as an application to a head-mounted display or a viewfinder, it is preferable that the display device be configured such that a display element and a driver are formed on the same semiconductor substrate, or the like.

The display device may have a so-called monochrome display configuration or a color display configuration. In a case where a color display configuration is employed, one color pixel can be configured including a plurality of pixels, specifically, one color pixel can be configured including a set of a red display pixel, a green display pixel, and a blue display pixel. Moreover, one color pixel can be configured including one set in which one or a plurality of types of pixels is further added to these three types of pixels.

Although, some resolutions for image display, such as U-XGA (1600, 1200), HD-TV (1920, 1080), or Q-XGA (2048, 1536), as well as (3840, 2160), (7680, 4320) or the like, can be exemplified as a value of a pixel (pixel) of the display device, the resolution for the image display is not limited to these values.

Furthermore, various kinds of electronic apparatuses being a direct-view type or projection type display device or including an image display function can be exemplified as an electronic apparatus including a display device according to the present disclosure.

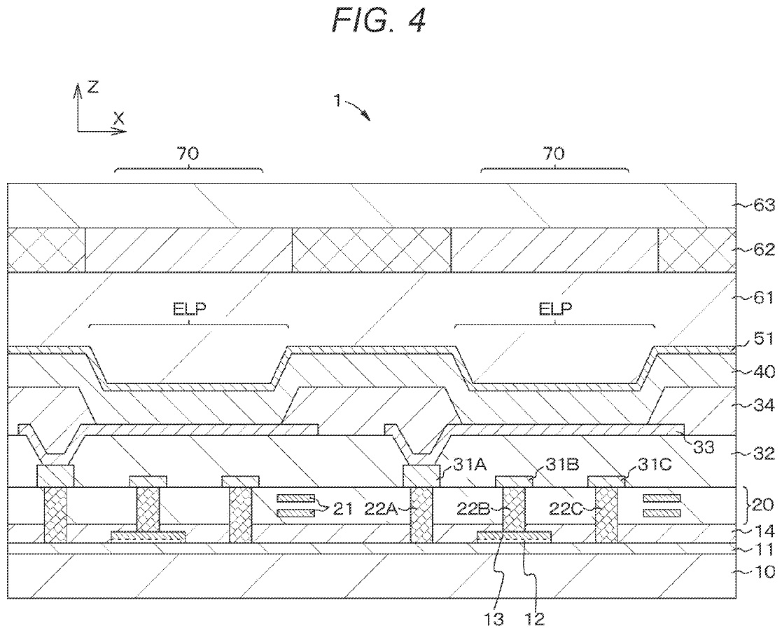

Various conditions in the present specification are satisfied not only in a case of being mathematically strictly met but also in a case of being substantially met. Presence of various variations in design or manufacturing variations is acceptable. Furthermore, each of the drawings used in the following description is a schematic one and does not illustrate actual dimensions or a ratio thereof. For example, FIG. 4, which will be described later, illustrates a cross-sectional structure of the display device, but not a ratio between width, height, and thickness thereof.

### First Embodiment

A first embodiment relates to a display device and electronic apparatus according to the present disclosure.

FIG. 1 is a conceptual diagram of a display device according to the first embodiment.

An overview of the display device will be described. A display device 1 has a pixel array unit 80 in which display elements 70 that constitute pixels are arranged in a two-dimensional matrix in a row direction and a column direction. Furthermore, the display device 1 includes a scanning wire WS and power supply line PS1 provided for each of pixel rows arranged along the row direction (X direction in FIG. 1) and a data line DTL provided for each of pixel columns arranged along the column direction (Y direction in FIG. 1). The respective display elements 70 are arranged in a two-dimensional matrix of N number in the row direction and in the M number in the column direction, for a total number of N×M, while being connected to a scanning wire WS, a power supply line PS1, and data line DTL.

The pixel array unit 80 that displays an image is configured by the display elements 70 arranged in a two-dimensional matrix. The number of rows of the display elements 70 in the pixel array unit 80 is M, and the number of display elements 70 that constitute each of the row is N. In the following description, there may be a case where a display element 70 is referred to as a pixel 70.

The number of each of the scanning wires WS and power supply lines PS1 is M. A pixel 70 of an m-th row (where, m=1, 2 . . . , M) is connected to an m-th scanning wire WSₘ and an m-th power supply line PS1ₘ, and constitutes one pixel row. Furthermore, the number of data lines DTL is N. A pixel 70 in an n-th column (where n=1, 2 . . . , N) is connected to an n-th data line DTLₙ.

Note that, although illustration is omitted in FIG. 1, the display device 1 includes unillustrated various wirings such as a common power supply line commonly connected to all the pixels 70.

The display device 1 includes a source driver 110 for driving the pixel array unit 80, a vertical scanner 120, and a power supply unit 130.

The pixel array unit 80 is formed on a substrate 10 on which a semiconductor material layer including silicon, for example, is formed. Note that the source driver 110, the vertical scanner 120, and the power supply unit 130 are also formed on the substrate 10. That is, the display device 1 is a display device integrated with a driver circuit. Note that, in some cases, various circuits for driving the pixel array unit 80 may be configured as a separate body.

To the source driver 110, a signal LD_{Sig} representing gradation corresponding to an image to be displayed is input from, for example, an unillustrated device. The signal LD_{Sig} is, for example, a low voltage digital signal. The source driver 110 generates an analog signal corresponding to a gradation value of a video signal LD_{Sig} and supplies the analog signal, as a video signal, to the data line DTL. An analog signal to be generated is a signal having a maximum value voltage substantially equivalent to power supply voltage supplied to the source driver 110, and amplitude is about several volts.

The vertical scanner 120 supplies a scan signal to scanning wires WS. By the scan signal, pixels 70 are sequentially scanned in units of row, for example. The power supply unit 130 will be described as continuously supplying a predetermined power supply voltage V_{CC} (for example, about 10 volts) to a power supply line PS1 regardless of scanning by a scanning wire WS. Note that, in some cases, a configuration may be employed in which voltage supplied to a power supply line PS1 is switched in response to scanning by a scanning wire WS.

The display device 1 is, for example, a display device of color display, and a group of three pixels 70 arranged in the row direction constitutes one color pixel. Therefore, if N′=N/3, N′ color pixels are arranged N′ number in the row direction and in the M number in the column direction, for a total number of N′×M on the pixel array unit 80.

As described above, by a scan signal from the vertical scanner 120, pixels 70 are sequentially scanned in units of row, for example. A pixel 70 positioned in an m-th row and an n-th column is hereinafter referred to as an (n, m)-th pixel 70.

In the display device 1, N number of pixels 70 arranged in an m-th row are simultaneously driven. In other words, for N number of pixels 70 arranged along the row direction, a timing of emission or non-emission of light is controlled in units of row to which the pixels 70 belong. Given that a display frame rate of the display device 1 is represented as FR (times/second), a scan period per row (so-called horizontal scan period) when the display device 1 is sequentially scanned in units of row is shorter than (1/FR)×(1/M) seconds.

The overview of the display device 1 has been described above. Next, details of a pixel (display element) 70 will be described.

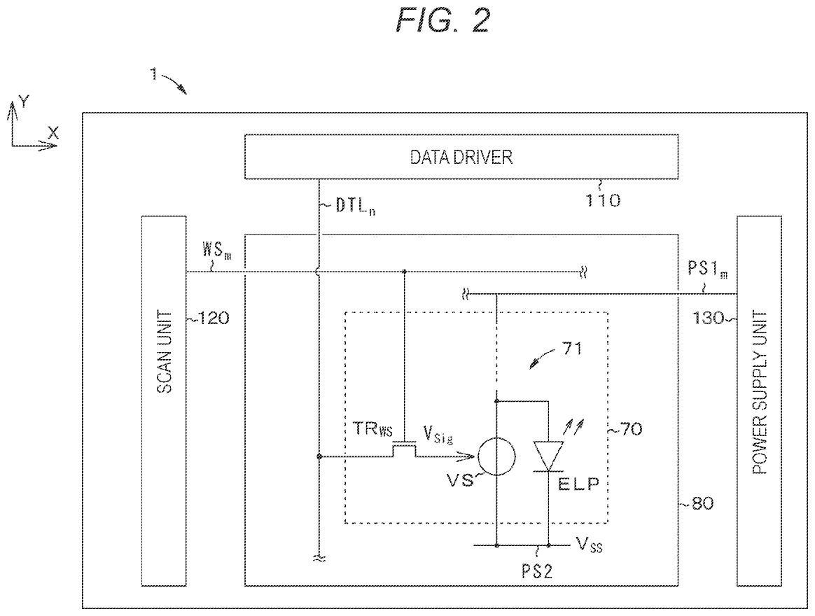

FIG. 2 is a schematic circuit diagram for describing basic operation of a pixel (display element) including a voltage drive type drive circuit. Note that, for convenience of illustration, FIG. 2 illustrates a wiring relation of one pixel 70, more specifically, an (n, m)-th pixel 70.

As illustrated in FIG. 2, a pixel (display element) 70 includes a light emission part ELP driven by current and a drive circuit 71 for driving the light emission part ELP. The drive circuit 71 has a configuration in which voltage of a voltage source VS for supplying voltage to one end (anode electrode) of the light emission part ELP is controlled by voltage V_{Sig} from a data line DTL. Another end (cathode electrode) of the light emission part ELP is connected to, for example, a common power supply line PS2, and common voltage V_{SS} (for example, ground potential) is supplied to the other end of the light emission part ELP.

Current corresponding to a V-I characteristic flows through the light emission part ELP according to potential difference (voltage) at both ends of the light emission part ELP. Because luminance of the light emission part ELP is determined by an amount of current that flows, a pixel including a voltage drive type drive circuit has a potential effect of variation in a V-I characteristic in the light emission part. Therefore, it is preferable to reduce another variation factor, more specifically, variation in voltage supplied to one end (anode electrode) of the light emission part ELP as much as possible.

As will be described below, in the first embodiment, variation in voltage supplied to the light emission part ELP is reduced by limiting configuration of a transistor that constitutes the voltage source VS.

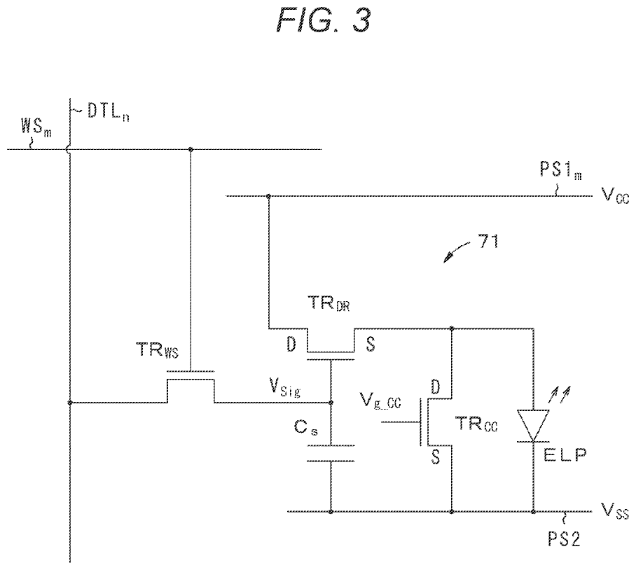

FIG. 3 is a schematic circuit diagram for describing a specific configuration of a drive circuit used in a display device.

In the first embodiment, the drive circuit 71 at least includes a constant current transistor TR_{CC}, a drive transistor TR_{DR} to which the light emission part ELP and a source electrode are connected, the drive transistor TR_{DR} being in source follower connection with the constant current transistor TR_{CC}, and a capacitance unit C_{S} that maintains gate voltage of the drive transistor TR_{DR}. The drive circuit 71 further includes a write transistor TR_{WS} for writing signal voltage V_{Sig} to the capacitance unit C_{S}.

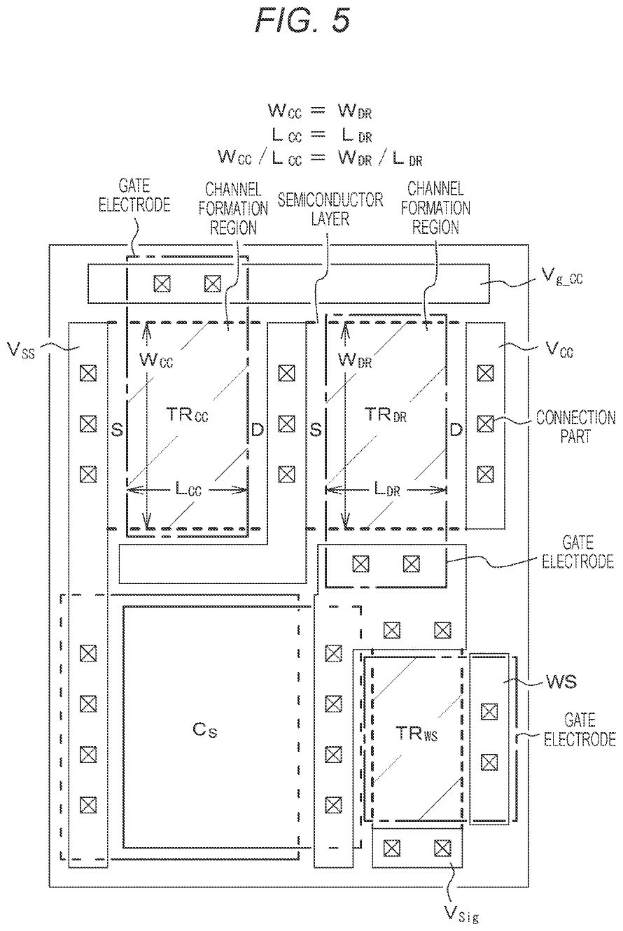

As will be described in detail later with reference to FIG. 5 and the like, the constant current transistor TR_{CC} and the drive transistor TR_{DR} are formed such that a ratio of a channel width to a channel length is the same. More specifically, the constant current transistor TR_{CC} and the drive transistor TR_{DR} are formed with the same transistor size. The constant current transistor TR_{CC} and the drive transistor TR_{DR} include a field-effect transistor of the same conductivity type (here, n-channel type). A similar applies to the write transistor TR_{WS}.

In the drive transistor TR_{DR}, one source/drain electrode is connected to the power supply line PS1, and a predetermined drive voltage V_{CC} is applied to the source/drain electrode. Furthermore, another source/drain electrode is connected to one source/drain electrode of the constant current transistor TR_{CC} and one end (anode electrode) of the light emission part ELP. The other source/drain electrode of the constant current transistor TR_{CC} is connected to the common power supply line PS2. Gate voltage V_{g_CC}, which will be described later, is applied to a gate electrode of the constant current transistor TR_{CC}. Note that, although another end (cathode electrode) of the light emission part ELP and another source/drain electrode of the constant current transistor TR_{CC} are both connected to the common power supply line PS2 in the example illustrated in FIG. 3, these may be configured connected to separate power supply lines to be supplied with voltage from separate power supplies.

In the write transistor TR_{WS}, one source/drain electrode is connected to the data line DTL and the gate electrode is connected to the scanning wire WS. The other source/drain electrode of the write transistor TR_{WS} and one electrode of the capacitance unit C_{S} are connected to a gate electrode of the drive transistor TR_{DR}. The other electrode of the capacitance unit C_{S} is connected to the common power supply line PS2, and voltage V_{SS} is supplied.

The light emission part ELP is a current-driven light emission part of which light emission luminance changes according to a value of flowing current, and specifically includes an organic electroluminescence light emission part. The light emission part ELP has a known configuration or structure including an anode electrode, a hole-transport layer, a light emission layer, an electron transport layer, a cathode electrode, or the like.

Hereinafter, regarding the drive transistor TR_{DR} and the constant current transistor TR_{CC}, one source/drain electrode is simply referred to as a drain electrode, and another source/drain electrode is simply referred to as a source electrode. An overview of drive in the drive circuit 71 will be described.

After signal voltage V_{Sig} is applied to a gate electrode of the drive transistor TR_{DR} from the data line DTL via the write transistor TR_{WS} that is turned to be conductive by a scan signal from the scanning wire WS, the write transistor TR_{WS} is turned to be non-conductive. The capacitance unit C_{S} maintains gate voltage of the drive transistor TR_{DR} for one frame period.

Voltage of the constant current transistor TR_{CC} is set to function as a constant current source. The drive transistor TR_{DR} is in source follower connection, and source voltage of the drive transistor TR_{DR} is controlled by the gate voltage of the drive transistor TR_{DR}. Because the gate voltage of the drive transistor TR_{DR} is maintained for one frame period, source voltage corresponding to the gate voltage is output for the one frame period.

The source voltage of the drive transistor TR_{DR} corresponds to anode voltage of the light emission part ELP. Current that corresponds to potential difference between the anode electrode and the cathode electrode flows through the light emission part ELP, and the light emission part ELP emits light with luminance corresponding to a current value. As a result, luminance of the light emission part ELP is determined by the source voltage of the drive transistor TR_{DR}, and therefore, luminance of the light emission part ELP varies when the source voltage of the drive transistor TR_{DR} varies.

Here, three-dimensional arrangement relations in the light emission part ELP, the transistors, or the like will be described. FIG. 4 is a schematic partial cross-sectional view of a part of a pixel array unit, the part including a pixel.

The substrate 10 includes, for example, a glass material. A drive circuit including a transistor that controls light emission of the light emission part ELP is formed on the substrate 10.

A semiconductor material layer 11 including silicon for example is formed on the substrate 10, and gate electrodes 13 of various transistors that constitute the drive circuit 71 are formed on the semiconductor material layer 11. The reference sign 12 indicates a gate insulation film. A gate electrode 13 can be formed by using, for example, metal such as aluminum (Al), or polysilicon. The gate insulation film 12 can be formed by using, for example, silicon oxide (SiOₓ), silicon nitride (SiNₓ), or the like.

The semiconductor material layer 11 can be formed by using amorphous silicon, polycrystalline silicon, an oxide semiconductor, or the like. Furthermore, a partial region of the semiconductor material layer 11 is doped with an impurity to form a source/drain region. Moreover, a region of the semiconductor material layer 11 forms a channel region, the region of the semiconductor material layer 11 being positioned between one source/drain region and another source/drain region and positioned below the gate electrode 13. Thus, a top-gate type thin-film transistor is formed on the substrate 10. Note that, for convenience of illustration, display of the source/drain region and the channel region is omitted. Furthermore, for convenience of illustration, only the drive transistor TR_{DR} is illustrated in FIG. 2.

An interlayer insulation film 14 is formed on an entire surface including the gate electrode 13. The interlayer insulation film 14 includes, for example, silicon oxide (SiOₓ), silicon nitride (SiNₓ), silicon oxynitride (SiOₓN_{y}), or the like. Thereon, a wiring layer 20 including various electrodes and wirings is formed. Various electrodes and wirings are schematically illustrated by using a reference sign 21.

Various vias 22A, 22B, and 22C connected to a transistor are formed on the wiring layer 20. Then, various wirings and contacts (represented by reference signs 31A, 31B, or 31C) connected to the vias are formed on the wiring layer 20. These can include, for example, a metal material, or the like.

Then, a flattening film 32 is formed so as to cover an entire surface of the wiring layer 20. The flattening film 32 is formed to cover and flatten a surface. The flattening film 32 can be formed by using an organic insulation film including polyimide resin, acrylic resin, novolak resin or the like, or an inorganic insulation film including silicon oxide (SiOₓ), silicon nitride (SiNₓ), or silicon acid nitride (SiₓN_{y}), or the like.

Anode electrodes 33 are formed by being arranged on flattening films 32 in a two-dimensional matrix. An anode electrode 33 is connected to a source/drain electrode of the drive transistor TR_{DR} via the contact 31A and the via 22A. Note that the figure is schematically illustrated, and does not illustrate all components of the drive circuit 71 illustrated in FIG. 3. For example, illustration of electrodes that constitute the capacitance unit C_{S} illustrated in FIG. 3 is omitted.

A partition wall part 34 is provided between adjacent anode electrodes 33, and separates each of the anode electrodes 33. The partition wall part 34 can be formed by using inorganic oxide, inorganic nitride, inorganic oxynitride, a resin material, or the like.

The organic layer 40 is formed on an entire surface including a top of the anode electrode 33 and a top of the partition wall part 34. The organic layer 40 includes a light emission layer commonly formed for each of the anode electrodes 33, and emits white light. Then, a transparent cathode electrode 51 is formed on an entire surface including a top of the organic layer 40.

The organic layer 40 is formed by a plurality of stacked material layers such as, from a side close to the anode electrode 33, a hole injection layer, a hole transport layer, a red light emission layer, a luminescence separation layer, a blue light emission layer, a green light emission layer, or an electron transport layer. Note that, in the figure, the organic layer 40 is illustrated as a single layer.

The transparent cathode electrode 51 is formed on the entire surface including the top of the organic layer 40. The cathode electrode 51 includes a material having good light transmission and a small work function. The light emission part ELP illustrated in FIG. 3 is configured by a portion where the anode electrode 33, the organic layer 40, and the cathode electrode 51 are stacked.

A protection film 61 is formed on an entire surface including a top of the cathode electrode 51. The protection film 61 is for preventing invasion of water into the organic layer 40, and is formed by using a material having low water permeability. A counter substrate 63 on which a color filter 62 is formed is disposed on the protection film 61. The counter substrate 63 can be disposed on the protection film 61 by being bonded by using ultraviolet-curing resin, thermosetting resin, or the like.

The three-dimensional arrangement relations in the light emission part ELP, the transistors, or the like have been described. Next, planar disposition of the transistors or the like on the drive circuit will be described.

FIG. 5 is a schematic plan view for describing disposition of the transistors and the like on the drive circuit according to the first embodiment.

As illustrated in the figure, the drive transistor TR_{DR}, the constant current transistor TR_{CC}, the write transistor TR_{WS}, and the capacitance unit C_{S} are disposed on a plane region where the drive circuit is disposed. In the figure, the drive transistor TR_{DR} and the constant current transistor TR_{CC} are disposed on an upper stage side, and the write transistor TR_{WS} and the capacitance unit C_{S} are disposed on a lower stage side. Then, the constant current transistor TR_{CC} and the drive transistor TR_{DR} are formed adjacent to each other on the plane region where the drive circuit is disposed.

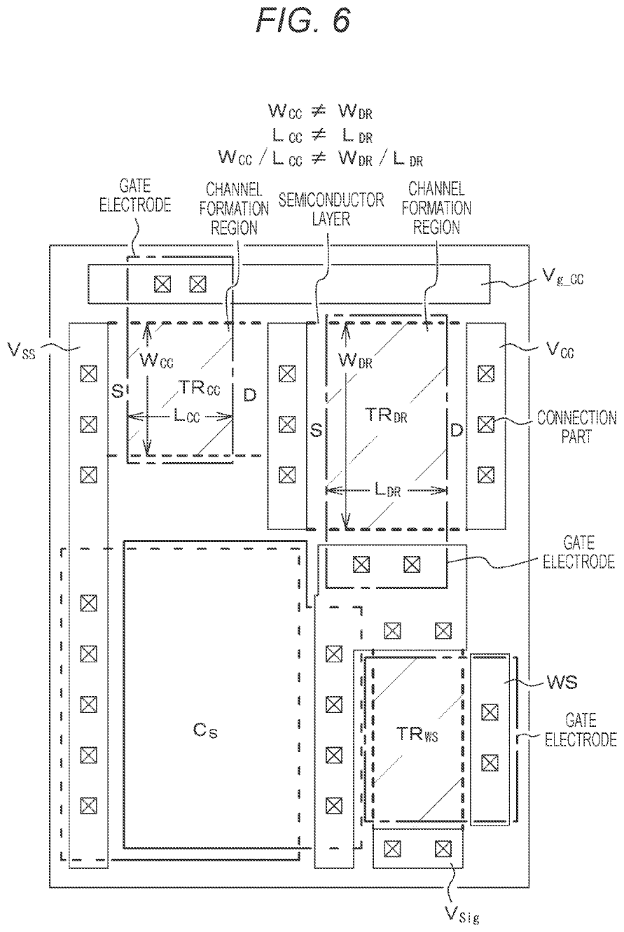

Note that portions for the semiconductor material layers that constitute each of the transistors are indicated by thick dashed lines, and portions for the gate electrodes are indicated by thick alternate long and short dash lines. A similar applies to FIGS. 6, 7, 8 and 9 described later.

Then, the constant current transistor TR_{CC} and the drive transistor TR_{DR} are formed such that a ratio of a channel width to a channel length is the same. More specifically, the constant current transistor TR_{CC} and the drive transistor TR_{DR} are formed with the same transistor size. If a channel length and channel width of the constant current transistor TR_{CC} are represented by a reference sign L_{CC} and a reference sign W_{CC}, and a channel length and channel width of the drive transistor TR_{DR} are represented by a reference sign L_{DR} and a reference sign W_{DR}, the following formula holds.

W_{CC}=W_{DR}

L_{CC}=L_{DR}

W_{CC}/L_{CC}=W_{DR}/L_{DR}

By setting in such a way, it is possible to reduce variation in the source voltage of the drive transistor TR_{DR} as described below.

A relation between the gate voltage and source voltage of the drive transistor TR_{DR} will be described.

In the following description, a gate voltage, drain voltage, source voltage, and threshold voltage of the drive transistor TR_{DR} are represented by a reference sign V_{g_DR}, reference sign V_{d_DR}, reference sign V_{s_DR}, and reference sign V_{th_DR}, respectively. Similarly, a gate voltage, drain voltage, source voltage, and threshold voltage of the constant current transistor TR_{CC} are represented by a reference sign V_{g_CC}, reference sign V_{d_CC}, reference sign V_{s_CC}, and reference sign V_{th_CC}, respectively.

It is assumed that voltage of each of the transistors that constitute pixels is set such that the transistors operate in a saturation region. Therefore, in the drive transistor TR_{DR}, the formula

V_{gs_DR}−V_{th_DR}<V_{ds_DR} (1) holds.

Furthermore, drain current I_{ds_DR} that flows through the drive transistor TR_{DR} is represented as

I_{ds_DR}=(½)·β_{DR}·(V_{g_DR}−V_{s_DR}−V_{th_DR})² (2).

Note that the formula

β_{DR}≡β_{DR}·(W_{DR}/L_{DR})·C_{ox_DR}

holds where

μ_{DR}: effective mobility in drive transistor TR_{DR}

L_{DR}: channel length of drive transistor TR_{DR}

W_{DR}: channel width of drive transistor TR_{DR}

C_{ox_DR}: (relative permittivity of gate insulation layer)×(vacuum permittivity)/(thickness of gate insulation layer) in drive transistor TR_{DR}.

Next, current that flows through the constant current transistor TR_{CC} will be described. Voltage of the transistor is set such that the transistor operates in a saturation region, and if V_{s_CC}=V_{SS}=0 [volts], drain current I_{ds_CC} that flows through the constant current transistor TR_{CC} is represented as

I_{ds_CC}=(½)·β_{CC}·(V_{g_CC}−V_{th_CC})² (3).

Note that the formula

β_{CC}≡μ_{CC}·(W_{CC}/L_{CC})·C_{ox_CC}

holds where

μ_{CC}: effective mobility in constant current transistor TR_{CC}

L_{CC}: channel length of constant current transistor TR_{CC}

W_{CC}: channel width of constant current transistor TR_{CC}

C_{ox_CC}: (relative permittivity of gate insulation layer)×(vacuum permittivity)/(thickness of gate insulation layer) in constant current transistor TR_{CC}.

Here, in a case where no current flows through the light emission part ELP, the formula I_{ds_DR}=I_{ds_CC} holds. At this time, from the above-described formula (2) and formula (3), the following formula holds.

β_{DR}·(V_{g_DR}−V_{s_DR}−V_{th_DR})²=β_{CC}·(V_{g_CC}−V_{th_CC})² (4)

If the above-described formula (4) is solved for V_{s_DR}, the following formula holds.

V_{s_DR}=V_{g_DR}−V_{th_DR}−(β_{CC}/β_{DR})^{1/2}·(V_{g_CC}−V_{th_CC}) (5)

As described above, because V_{s_DR} is an anode voltage of the light emission part ELP, luminance of the pixel is determined by a value of V_{s_DR}.

Here, the above-described formula (5) shows that V_{s_DR} is determined by the following six factors.
V_{g_DR}: gate voltage of drive transistor TR_{DR}, that is, signal voltage V_{Sig}
V_{th_DR}: threshold voltage of drive transistor TR_{DR},
β_{DR}: β value of drive transistor TR_{DR}
V_{g_CC}: gate voltage of constant current transistor TR_{CC}
V_{th_CC}: threshold voltage of constant current transistor TR_{CC}
β_{CC}: β value of constant current transistor TR_{CC}

Of the six factors that determine V_{s_DR}, items for which variation among pixels of display device 1 can be ignored are a first V_{g_DR} and a fourth V_{g_CC}, both of which are gate voltage of the transistor. The former is a signal voltage V_{Sig}, and voltage corresponding to luminance of the image to be displayed is supplied from outside. Therefore, variation among pixels can be ignored. Furthermore, although the latter is voltage supplied to drive the transistor as a constant current source, it is not realistic to adjust this voltage for each pixel. Therefore, because the same voltage is basically supplied to all the pixels, variation among pixels can be ignored.

Here, the above-described formula (5) is transformed into a form including addition and subtraction of three terms as below.

V_{s_DR}=V_{g_DR}

−(β_{CC}/β_{DR})^{1/2}·V_{g_CC}

+(β_{CC}/β_{DR})^{1/2}·(V_{th_CC}−V_{th_DR}) (6)

The above-described formula (6) shows that a value of V_{s_DR} is determined by three terms. That is,
first term including gate voltage V_{g_DR} of drive transistor TR_{DR}
second term including β value of drive transistor TR_{DR} and β value of constant current transistor TR_{CC}, as well as gate voltage V_{g_CC} of constant current transistor TR_{CC}
third term including β value of drive transistor TR_{DR} and β value of constant current transistor TR_{CC}, as well as threshold voltage V_{th_DR} of drive transistor TR_{DR} and threshold voltage V_{th_CC} of constant current transistor TR_{CC}.

Here, a biggest factor of variation among pixels is threshold voltage of a transistor that constitutes a pixel. Variation in threshold voltage causes variation of the third term among the above-described three terms. As a result, luminance in each pixel varies.

The present disclosure focuses on this point. Then, variation in luminance in each pixel is reduced by uniforming channel lengths and channel widths of the constant current transistor TR_{CC} and drive transistor TR_{DR}.

As illustrated in FIG. 5, in a configuration in which the channel lengths and channel widths of the drive transistor TR_{DR} and the constant current transistor TR_{CC} are in uniform, β_{DR}≈β_{CC} holds. Therefore, given that the above-described formula (6) holds when (β_{CC}/β_{DR})=1, the formula (6) is transformed as below.

V_{s_DR}≈V_{g_DR}−V_{g_CC}+(V_{th_CC}−V_{th_DR}) (7)

Furthermore, because difference in threshold voltage among the transistors in the same pixel is very small, the formula V_{th_DR}≈V_{th_CC} holds. Therefore, the above-described formula (7) is expressed as V_{s_DR}≈V_{g_DR}−V_{g_CC} (8).

Meanwhile, as illustrated in FIG. 6, disposition in a case of formation of the constant current transistor TR_{CC} and the drive transistor TR_{DR} satisfies

W_{CC}≠W_{DR}

L_{CC}≠L_{DR}

W_{CC}/L_{CC}≠W_{DR}/L_{DR},

the above-described formula (6) does not hold when β_{CC}/(β_{DR})=1. Therefore, V_{s_DR} cannot be treated as in the formula (8) and the variation of the third term in the formula (6) remains.

As described above, as illustrated in FIG. 5, in a configuration in which the channel lengths and channel widths of the drive transistor TR_{DR} and the constant current transistor TR_{CC} are in uniform, V_{s_DR} is basically determined by a gate voltage V_{g_DR} and gate voltage V_{g_CC}.

Then, the gate voltage V_{g_DR} and the gate voltage V_{g_CC} are voltages at which variation among the pixels can be ignored. Therefore, because variation in V_{s_DR} among the pixels is reduced, variation in luminance in each pixel can be reduced. Furthermore, there is little difference in electrical characteristics, because the constant current transistor TR_{CC} and the drive transistor TR_{DR} are formed adjacent to each other on the plane region where the drive circuit is disposed. With this arrangement, the variation can be further reduced.

Next, various modifications will be described.

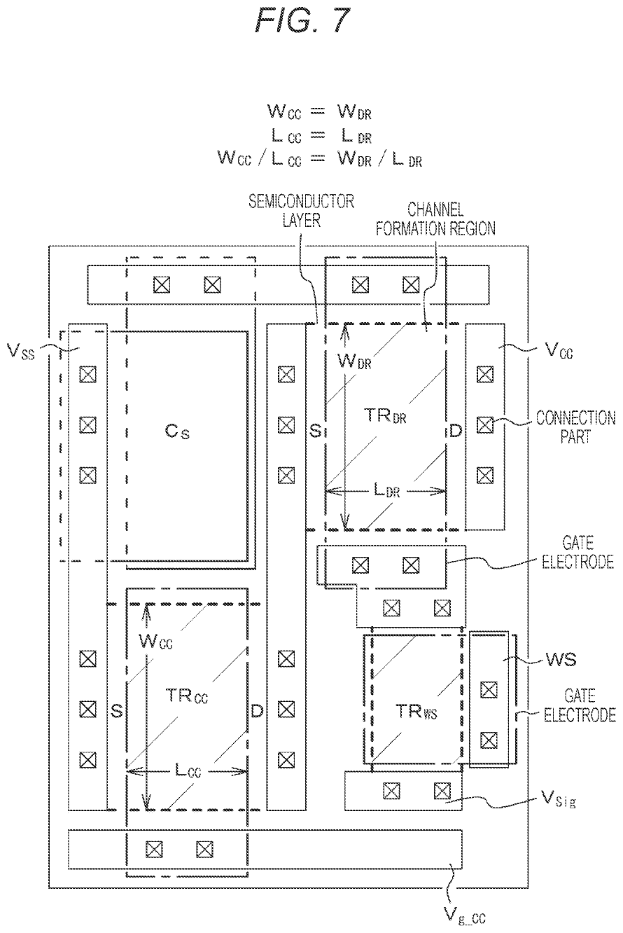

FIG. 7 is a schematic plan view for describing disposition of the transistors and the like in a drive circuit of a first modification.

In FIG. 7 also, the drive transistor TR_{DR}, the constant current transistor TR_{CC}, the write transistor TR_{WS}, and the capacitance unit C_{S} are disposed on the plane region where the drive circuit is disposed. In the figure, the capacitance unit C_{S} and the drive transistor TR_{DR} are disposed on the upper stage side, and the constant current transistor TR_{CC} and the write transistor TR_{WS} are disposed on the lower stage side. The constant current transistor TR_{CC} and the drive transistor TR_{DR} are disposed diagonally to each other. In this example also, the following formula holds.

W_{CC}=W_{DR}

L_{CC}=L_{DR}

W_{CC}/L_{CC}=W_{DR}/L_{DR} However, because the constant current transistor TR_{CC} and the drive transistor TR_{DR} are not adjacent to each other, the disposition illustrated in FIG. 5 is more advantageous in terms of having the same transistor characteristic.

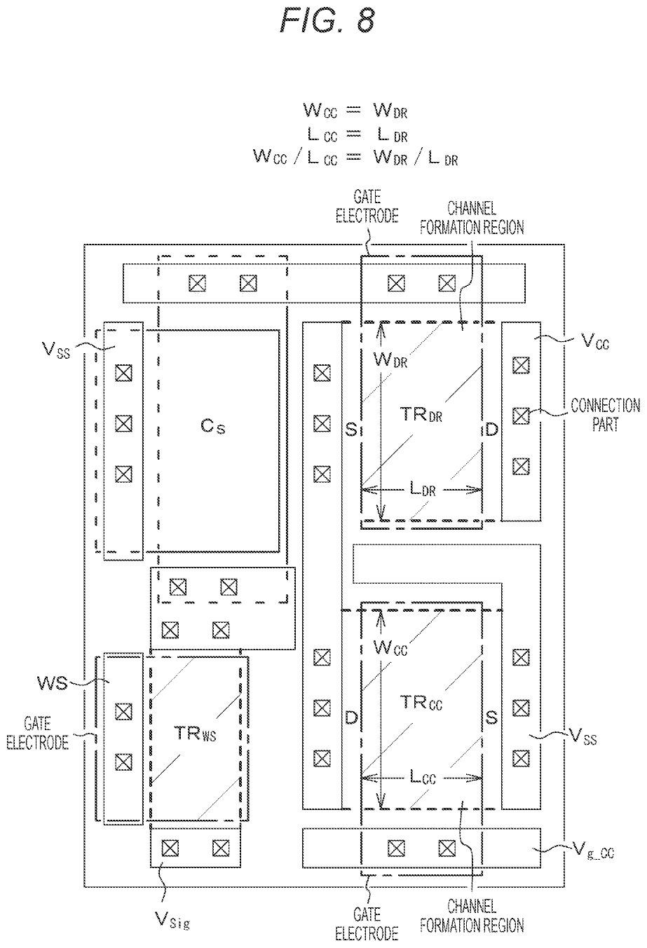

FIG. 8 is a schematic plan view for describing disposition of the transistors and the like in a drive circuit of a second modification.

In FIG. 8 also, the drive transistor TR_{DR}, the constant current transistor TR_{CC}, the write transistor TR_{WS}, and the capacitance unit C_{S} are disposed on the plane region where the drive circuit is disposed. In the figure, the capacitance unit C_{S} and the write transistor TR_{WS} are disposed on a left side, and the drive transistor TR_{DR}, the write transistor TR_{WS}, and the constant current transistor TR_{CC} are disposed on a right side. Then, the constant current transistor TR_{CC} and the drive transistor TR_{DR} are disposed adjacent to each other, aligned in a vertical direction. In this example also, the following formula holds.

W_{CC}=W_{DR}

L_{CC}=L_{DR}

W_{CC}/L_{CC}=W_{DR}/L_{DR} Because the constant current transistor TR_{CC} and the drive transistor TR_{DR} are adjacent to each other, it is possible to obtain an effect similar to an effect in FIG. 5 in terms of having the same transistor characteristic.

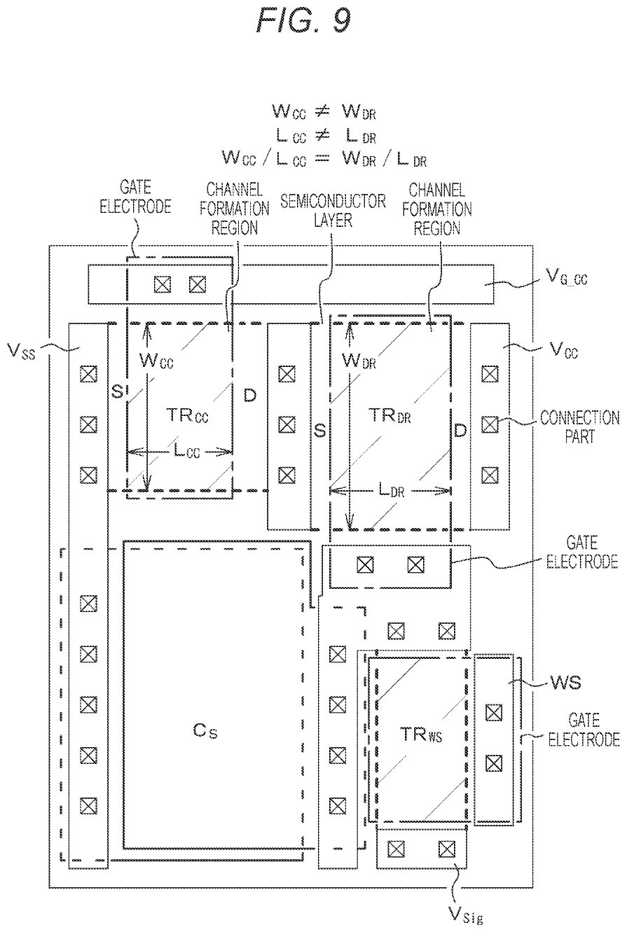

FIG. 9 is a schematic plan view for describing disposition of the transistors and the like in a drive circuit of a third modification.

In FIG. 9 also, the drive transistor TR_{DR}, the constant current transistor TR_{CC}, the write transistor TR_{WS}, and the capacitance unit C_{S} are disposed on the plane region where the drive circuit is disposed. In the figure, the drive transistor TR_{DR} and the constant current transistor TR_{CC} are disposed on an upper stage side, and the write transistor TR_{WS} and the capacitance unit C_{S} are disposed on a lower stage side. Then, the constant current transistor TR_{CC} and the drive transistor TR_{DR} are formed adjacent to each other on the plane region where the drive circuit is disposed. Although the constant current transistor TR_{CC} is smaller than the drive transistor TR_{DR}, a relation

W_{CC}/L_{CC}=W_{DR}/L_{DR}

is maintained. Even in this configuration, (β_{CC}/β_{DR}) can be basically treated as about 1, and therefore, variation in V_{s_DR} among the pixels can be reduced.

In various display devices according to the present disclosure described above, a constant current transistor and a drive transistor are formed such that a ratio of a channel width to a channel length is the same. With this arrangement, it is possible to supply voltage, with as little variation as possible among display elements, to a light emission part of the display elements that constitute pixels. Furthermore, according to an electronic apparatus using a display device according to the present disclosure, it is possible to display an image with little variation in luminance.

[Electronic Apparatus]

The display device according to the present disclosure described above can be used as a display unit (display device) of an electronic apparatus in all fields for displaying a video signal input to the electronic apparatus or a video signal generated in the electronic apparatus as an image or a video. As an example, for example, the display device can be used as a display unit of a television set, a digital still camera, a notebook personal computer, a mobile terminal device such as a mobile phone, a video camera, or a head-mounted display (display to be worn on a head).

Examples of a display device according to the present disclosure also include a modular display device having a sealed configuration. An example is a display module formed by a counter part, such as transparent glass, being attached to a pixel array unit. Note that the display module may be provided with a circuit unit, a flexible printed circuit (FPC), or the like for inputting/outputting a signal or the like from outside to the pixel array unit. Hereinafter, a digital still camera and a head-mounted display will be exemplified as specific examples of an electronic apparatus using a display device according to the present disclosure. However, the specific examples exemplified here are merely examples, and are not limited to these.

### Specific Example 1

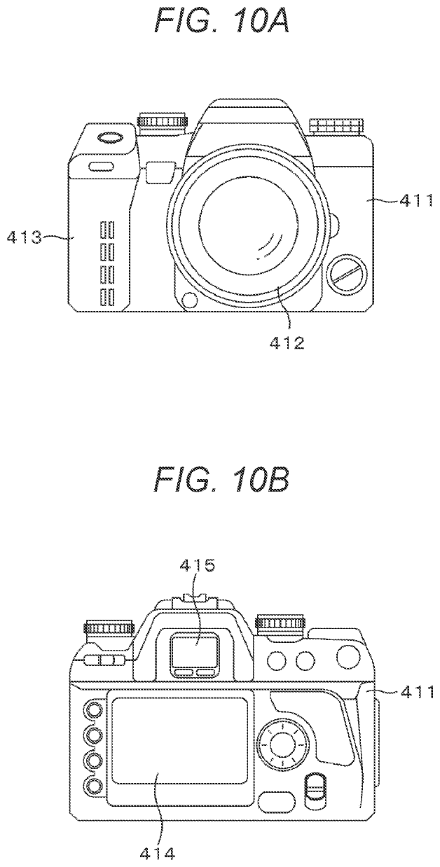

FIG. 10 is an external view of a lens interchangeable single-lens reflex type digital still camera of which front view is illustrated in FIG. 10A and rear view is illustrated in FIG. 10B. For example, the lens interchangeable single-lens reflex type digital still camera has an interchangeable image capturing lens unit (interchangeable lens) 412 on a front right side of a camera main body unit (camera body) 411, and has a grip part 413 on a front left side, the grip part 413 being to be held by a person who takes an image.

Then, a monitor 414 is provided substantially in a center of a back surface of the camera main body unit 411. A viewfinder (eyepiece window) 415 is provided above the monitor 414. By looking into the viewfinder 415, the person who takes an image can visually recognize an optical image of a subject guided by the image capturing lens unit 412 and determine a composition.

In the lens interchangeable single-lens reflex type digital still camera having the above-described configuration, a display device according to the present disclosure can be used as the viewfinder 415. That is, a lens interchangeable single-lens reflex type digital still camera according to the present example is manufactured by using, as the viewfinder 415, the display device according to the present disclosure. Furthermore, similarly, a display device according to the present disclosure can be used for the monitor 414 disposed on the back surface.

### Specific Example 2

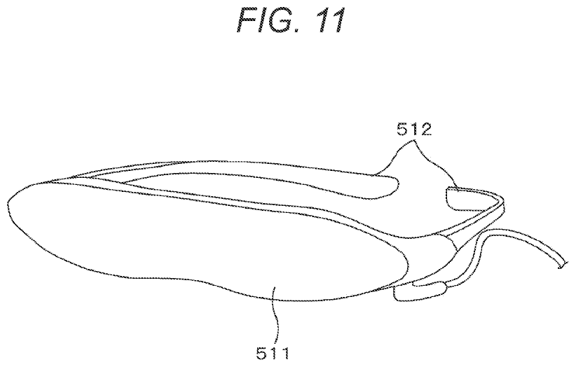

FIG. 11 is an external view of a head-mounted display. The head-mounted display has, for example, ear hook parts 512 on both sides of an eyeglass-shape display unit 511, the ear hook parts 512 being to be worn by a head of a user. In the head-mounted display, a display device according to the present disclosure can be used as the display unit 511. That is, a head-mounted display according to the present example is manufactured by using, as the display unit 511, the display device according to the present disclosure.

### Specific Example 3

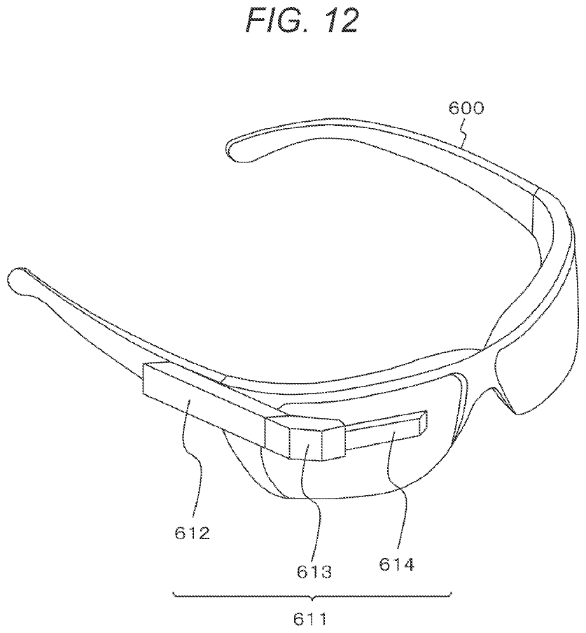

FIG. 12 is an external view of a see-through head-mounted display. A see-through head-mounted display 611 includes a main body unit 612, an arm 613, and a lens barrel 614.

The main body unit 612 is connected to the arm 613 and eyeglasses 600. Specifically, an end of the main body unit 612 in a long side direction is combined with the arm 613, and one side of a side surface of the main body unit 612 is coupled to the eyeglasses 600 via a connection member. Note that the main body unit 612 may be directly attached to a head of a human body.

The main body unit 612 incorporates a control substrate for controlling operation of the see-through head-mounted display 611 or a display unit. The arm 613 connects the main body unit 612 and the lens barrel 614 to support the lens barrel 614. Specifically, the arm 613 is combined to each of an end of the main body unit 612 and an end of the lens barrel 614 to fix the lens barrel 614. Furthermore, the arm 613 incorporates a signal line for communicating data related to an image provided from the main body unit 612 to the lens barrel 614.

Toward eyes of a user wearing the see-through head-mounted display 611, the lens barrel 614 projects, through an eye lens, image light provided from the main body unit 612 via the arm 613. In the see-through head-mounted display 611, a display device according to the present disclosure can be used for the display unit of the main body unit 612.

[Other]

Note that a technique according to the present disclosure may also be configured as below.

[A1]

A display device having

a pixel array unit in which display elements that constitute pixels are arranged in a two-dimensional matrix in a row direction and a column direction,

in which a display element includes a light emission part driven by current and a drive circuit for driving the light emission part,

the drive circuit at least includes

a constant current transistor,

a drive transistor to which the light emission part and a source electrode are connected, the drive transistor being in source follower connection with the constant current transistor, and

a capacitance unit that maintains gate voltage of the drive transistor, and

the constant current transistor and the drive transistor are formed such that a ratio of a channel width to a channel length is the same.

[A2]

The display device according to [A1] described above,

in which the constant current transistor and the drive transistor are formed with the same transistor size.

[A3]

The display device according to [A1] or [A2] described above,

in which the constant current transistor and the drive transistor are formed adjacent to each other on a plane region where the drive circuit is disposed.

[A4]

The display device according to any one of [A1] to [A3] described above,

in which the constant current transistor and the drive transistor include a field-effect transistor of the same conductivity type.

[A5]

The display device according to any one of [A1] to [A4] described above,

in which the light emission part includes an organic electroluminescence element.

[A6]

The display device according to any one of [A1] to [A5] described above,

in which the drive circuit further includes a write transistor for writing signal voltage to a capacitance unit.

[A7]

The display device according to claim [A6] described above,

in which the constant current transistor, the drive transistor, and the write transistor include a field-effect transistor of the same conductivity type.

[B1]

An electronic apparatus having a display device including

a pixel array unit in which display elements that constitute pixels are arranged in a two-dimensional matrix in a row direction and a column direction,

in which a display element includes a light emission part driven by current and a drive circuit for driving the light emission part,

the drive circuit at least includes

a constant current transistor,

a drive transistor to which the light emission part and a source electrode are connected, the drive transistor being in source follower connection with the constant current transistor, and

a capacitance unit that maintains gate voltage of the drive transistor, and

the constant current transistor and the drive transistor are formed such that a ratio of a channel width to a channel length is the same.

[B2]

The electronic apparatus according to [B1] described above,

in which the constant current transistor and the drive transistor are formed with the same transistor size.

[B3]

The electronic apparatus according to [B1] or [B2] described above,

in which the constant current transistor and the drive transistor are formed adjacent to each other on a plane region where the drive circuit is disposed.

[B4]

The electronic apparatus according to any one of [B1] to [B3] described above,

in which the constant current transistor and the drive transistor include a field-effect transistor of the same conductivity type.

[B5]

The electronic apparatus according to any one of [B1] to [B4] described above,

in which the light emission part includes an organic electroluminescence element.

[B6]

The electronic apparatus according to any one of [B1] to [B5] described above,

in which the drive circuit further includes a write transistor for writing signal voltage to a capacitance unit.

[B7]

The electronic apparatus according to claim [B6] described above,

in which the constant current transistor, the drive transistor, and the write transistor include a field-effect transistor of the same conductivity type.

### REFERENCE SIGNS LIST

1 Display device
10 Substrate
11 Semiconductor material layer
12 Gate insulation layer
13 Gate electrode
14 Interlayer insulation film
20 Wiring layer
21 Various electrodes and wirings
22A, 22B, 22C Vias
31A, 31B, 31C Wirings and contacts
32 Flattening film
33 Anode electrode
34 Partition wall part
40 Organic layer
51 Cathode electrode
61 Protection film
62 Color filter
63 Counter substrate
70 Display element (pixel)
71 Drive circuit
80 Pixel array unit
110 Source driver
120 Vertical scanner
130 Power supply unit
TR_{CC} Constant current transistor
TR_{RD} Drive transistor
TR_{SWW} Write transistor
C_{S} Capacitance unit
ELP Organic electroluminescence light emission part
WS Scanning wire
DTL Data line
PS1 Power supply line
411 Camera main body unit
412 Image capturing lens unit
413 Grip part
414 Monitor
415 Viewfinder
511 Eyeglass-shape display unit
512 Ear hook parts
600 Eyeglasses
611 See-through head-mounted display
612 Main body unit
613 Arm
614 Lens barrel

1. A display device comprising
a pixel array unit in which display elements that constitute pixels are arranged in a two-dimensional matrix in a row direction and a column direction,
wherein a display element includes a light emission part driven by current and a drive circuit for driving the light emission part,
the drive circuit at least includes
a constant current transistor,
a drive transistor to which the light emission part and a source electrode are connected, the drive transistor being in source follower connection with the constant current transistor, and
a capacitance unit that maintains gate voltage of the drive transistor, and
the constant current transistor and the drive transistor are formed such that a ratio of a channel width to a channel length is a same.

2. The display device according to claim 1,
wherein the constant current transistor and the drive transistor are formed with a same transistor size.

3. The display device according to claim 1,
wherein the constant current transistor and the drive transistor are formed adjacent to each other on a plane region where the drive circuit is disposed.

4. The display device according to claim 1,
wherein the constant current transistor and the drive transistor include a field-effect transistor of a same conductivity type.

5. The display device according to claim 1,
wherein the light emission part includes an organic electroluminescence element.

6. The display device according to claim 1,
wherein the drive circuit further includes a write transistor for writing signal voltage to a capacitance unit.

7. The display device according to claim 6,
wherein the constant current transistor, the drive transistor, and the write transistor include a field-effect transistor of a same conductivity type.

8. An electronic apparatus comprising a display device having
a pixel array unit in which display elements that constitute pixels are arranged in a two-dimensional matrix in a row direction and a column direction,
wherein a display element includes a light emission part driven by current and a drive circuit for driving the light emission part,
the drive circuit at least includes
a constant current transistor,
a drive transistor to which the light emission part and a source electrode are connected, the drive transistor being in source follower connection with the constant current transistor, and
a capacitance unit that maintains gate voltage of the drive transistor, and
the constant current transistor and the drive transistor are formed such that a ratio of a channel width to a channel length is a same.
